(19) United States
(12) Patent Application Publication
(10) Pub. No.: US 2009/0008431 A1
(43) Pub. Date: Jan. 8, 2009

(54) Solderable EMI Gasket and Grounding Pad

(76) Inventors: Kossi Zonvide, Middletown, DE (US); Jeremy Trethewey, Elkton, MD (US)

Correspondence Address: W. L. Gore & Associates, Inc., 551 Paper Mill Road, P.O. Box 9206, Newark, DE, 19714-9206, US

(21) Appl. No.: 11/773,080

(22) Filed: Jul. 3, 2007

(51) Int. Cl. B23K 31/02; F16J 15/06; H05K 9/00; B05D 3/12

(52) U.S. Cl. 228/179.1; 174/356; 427/289

(57) ABSTRACT

Apparatus, which is useful as both a conductive gasket and a grounding pad, which has a compressible elastomeric substrate having at least one side surface and two ends, a conductive elastomeric layer adjacent to all of the side surfaces of the compressible substrate, and a metal layer adjacent to the conductive layer.

### FIELD OF THE INVENTION

This invention relates to grounding pads and electrically conductive gaskets, and in particular to such a device that is compressible and solderable.

### BACKGROUND OF THE INVENTION

“Signal Integrity” is a term used in the high-speed digital world to describe the management of primary or “wanted” signals in the transmission path. EMC, or Electromagnetic Compatibility, usually describes the management of “unwanted” signals in an electronic circuit or system. Traditionally, circuits were placed in metal enclosures creating a “Faraday cage” effect that would shield the electronic circuit or system from any unwanted signals. Conversely, the shield would prevent any wanted signals from escaping the enclosure.

Modern electronics have experienced trends such as the increased usage of handheld devices, higher wireless bandwidth, and faster computing speeds. These trends generate increasingly complex electronic circuits forcing designers to put more components per square inch onto the printed circuit board (PCB). Surface mount technology has afforded circuit designers the ability to put many more components per square inch, compared to older through-hole mounted components. This yields densely populated circuits, where available PCB real estate is becoming a scarce commodity. Even the surface mount components themselves have been getting smaller, with the advent of 0402 and 0201 passive devices and micro-BGA chipsets. With so many circuit elements being densely populated and cohabitating on the same PCB, the circuit designer is now faced with the challenge of providing shielding for the different circuits which are in such close proximity to each other. This challenge is made more difficult by the fact that available real-estate on the PCB where the shields would normally be attached is continually shrinking.

Traditional methods for providing multi-cavity shielding for PCBs include molding and metalizing a plastic housing that would encompass the entire PCB. The challenge for this technique is how to electrically and mechanically attach the shield to the board. An integrated EMI (Electromagnetic Interference) gasket on the shield and the use of screw type fasteners is one method of accomplishing this. Several other technologies have been introduced that can provide multi-cavity shields for densely populated PCBs. One technology is where a multi-cavity shield is electrically and mechanically attached to the ground trace of a PCB using special conductive adhesive. Another method uses a metalized thermoformed multi-cavity shield that is mechanically and electrically attached to the PCB using BGA solder balls. Although these technologies offer designers creative options for solving densely populated PCB shielding problems, they still require some design and tooling efforts in order to integrate them into the PCB assembly.

A class of grounding technologies exists that requires little to no up-front design and tooling for the engineer in order to integrate them into their PCB level shielding and grounding solutions. The reason for this is that this class of grounding technologies is inherently compatible with surface mount technology (SMT) and can be assembled onto the PCB along with the other electronic components. Standard tape-and-reel packaging allows these components to work with most pick-and-place SMT equipment. Individual parts may be used as discrete grounding points or placed in series to form an EMI gasket solution. Standard part geometries aid the engineer in laying out shielding and grounding areas only where they are needed, thus minimizing the overall real-estate used to electrically connect the ground plane of the PCB to the component, shield, or chassis.

One such form of a surface mount grounding pad or gasket is a conductive conformable material with an integrated shim layer that can be soldered to a ground trace of a PCB. The shim layer provides both mechanical support and a surface that is most compatible with solder materials used in the SMT process. The part geometries can also have features that will aid in vision placement and inspection. It is important to note that, although these patents describe an SMT compatible EMI gasket, they can be used in any grounding application where the designer wants to electrically connect the ground plane of the PCB to a component, shield, or some part of the device chassis. SMT compatible metal clips have been used in similar applications but suffer from potential damage, due to lack of robustness, and limited grounding, due to small surface area of the contact points. Another known EMI gasket exists using a non-conductive base material which then has a conductive metal layer applied over it. In this case the only path for current flow is through the metallization itself, which may become cracked or damaged with flexing and use, and thus provides an unreliable device.

### SUMMARY OF THE INVENTION

The present invention improves on the previous concepts by providing an SMT compatible grounding pad that has an inherently solderable surface. In this concept, the shim support layer is not needed to provide the interface between the conductive gasket material and the solder bond to the PCB ground trace. This approach allows for more flexibility in part shapes, lengths and geometries. The base material is comprised of a metal filled elastomer, or composite of a metal filled elastomer with another elastomer. The outside of the base material is then applied a continuous coating of metallization. The outer metal can be deposited by electroless plating or electrolytic plating technologies, or by vapor deposition of the metal, or any combination of these techniques. This outer metal layer provides a solderable surface for the solder paste to adhere to and attach to the ground trace of the PCB. It will also improve the surface conductivity of the invention by providing more surface area to connect to the corresponding component, shield, or chassis.

Since the base material is inherently conductive, it is not necessary for the outer metallization layer to be continuously conductive, although preferably it is. The outer conductive layer provides a mechanical and electrical interface between the solder and conductive particle dispersed within the top surface of the base material.

In particular, the present invention provides an apparatus which is useful as both a conductive gasket and a grounding pad, which has a compressible substrate having at least one side surface and two ends, a conductive layer adjacent to all of the side surfaces of the compressible substrate, and a metal layer adjacent to the conductive layer to enable solderability. Preferably, the compressible substrate is an elastomer, and the conductive layer is a conductive elastomer formed of an elastomer having conductive particles impregnated therein. The conductive particles are formed of silver, nickel, carbon, copper, aluminium, gold, tin, platinum, palladium, or combinations or alloys thereof. The elastomers used are preferably silicone, silicone gum, or rubber or combinations thereof. Alternatively, the compressible substrate is formed of materials such as, fluorocarbon, fluorosilicon, ethylene-propylene diene monomer (EPDM), polytetrafluoroethylene (PTFE), expanded polytetrafluoroethylene (ePTFE), or combinations thereof, or combinations with an elastomer. The metal layer is a metal plating or coating, where the metal is preferably copper, nickel, silver, gold, tin, chromium, or combinations or alloys thereof. The metal layer is preferably an electrolytically plated, an electrolessly plated, or a vapor deposited metal, or any combination thereof.

In alternative embodiments, the apparatus has a substantially round cross-section, a quadrilateral cross-section, a rectangular cross-section, a substantially square cross-section or an irregular cross-section. Alternatively, the apparatus is hollow or has a sponge core.

The apparatus is compressible to 75% of its height with an applied load less than 500 pounds per square inch, and has a DC resistance less than 50 mOhms when compressed to 75% of its height.

In another aspect, the invention provides a method of making a conductive gasket or grounding pad involving the steps of providing a continuous base material having compressible elastomeric substrate and a conductive elastomeric outer layer adjacent the resilient elastomeric substrate; electroplating the continuous base material to form a continuous conductive gasket or grounding pad, and cutting the continuous conductive gasket or grounding pad into a plurality of discrete conductive gaskets or grounding pads. The invention also provides a method of forming a conductive gasket comprising soldering a plurality of apparatus as described above onto a support such as a printed circuit board. The apparatus is preferably deposited using surface mount technology equipment. The grounding pad aspect of the invention is preferably formed in the same manner.

### BRIEF DESCRIPTION OF THE DRAWINGS

FIG. 1 is a perspective view of an exemplary embodiment of the present invention.

FIG. 2 is a cross-sectional view of another exemplary embodiment of the present invention.

FIG. 3 is a perspective view of another exemplary embodiment of the present invention.

FIG. 4 is a cross-sectional view of another exemplary embodiment of the present invention.

FIG. 5 is a cross-sectional view of another exemplary embodiment of the present invention.

### DETAILED DESCRIPTION OF THE INVENTION

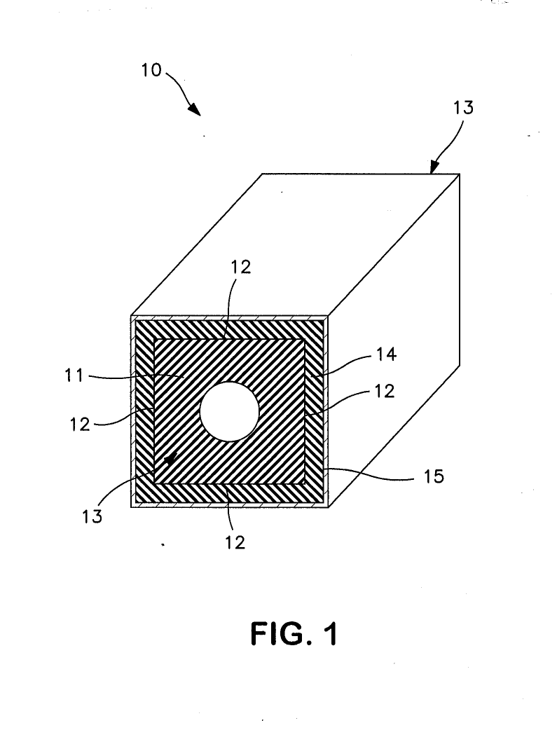

A preferred embodiment of the present invention is illustrated in FIG. 1. FIG. 1 shows an apparatus 10. Apparatus 10 can be either a grounding pad or a gasket. Typically, when used as a gasket, apparatus 10 is dispersed at a plurality of locations around, for example, a circuit board to create an interface between the PCB and the shield to form a Faraday cage to prevent EMI radiation being emitted from components on the circuit board. When used as a grounding pad, one or more of apparatus 10 may be disposed at various locations on, for example, a circuit board, to provide grounding locations for desired electrical performance. Apparatus 10 comprises a compressible elastomeric substrate 11. As used herein, compressible means compressible to 75% of its original (or uncompressed) height with an applied load of less than 500 pounds per square inch when compressed between two steel plates on a load frame at a rate of 1 mm per minute.

Compressible elastomeric substrate 11 has at least one side surface 12. In the embodiment illustrated in FIG. 1, apparatus 10 is quadrilateral, specifically rectangular. Thus, it has a rectangular cross section having four side surfaces 12. Although this is a preferred embodiment, alternative shapes for apparatus 10 are contemplated by this invention. For example and without limitation, apparatus 10 may be cylindrical (having one side surface 12), triangular, spherical, or otherwise. Alternatively, compressible elastomeric substrate 11 is hollow, or has a sponge core.

Adjacent to all of side surfaces 12 is conductive elastomeric layer 14. Compressible elastomeric substrate 11 and conductive elastomeric layer 14 are preferably constructed and formed together in accordance with the teachings of U.S. Pat. No. 4,968,854 (assigned to Vanguard Products Corporation), which is incorporated herein by reference in its entirety, with the exception that in the preferred embodiment of the present invention, compressible elastomeric substrate 11 is non-conductive.

Adjacent to conductive elastomeric layer 14 is a metal layer 15. Metal layer 15 is preferably a metal plated layer. For example, it may be deposited via electrolytic plating, electroless plating or vapor deposition or any combinations thereof. Metals such as copper, nickel, silver, gold, tin, chromium, and combinations and alloys thereof are suitable. Metal layer 15 provides a uniform, solderable surface for apparatus 10. Because metal layer 15 completely surrounds conductive elastomeric layer 14, any side of apparatus 10 can be disposed adjacent a circuit board, for example, for placement onto the PCB for solder attachment. Although the apparatus of the present invention may be placed by hand or by application specific installation tool, placement is preferably performed by automated SMT equipment. Because there is no particular orientation necessary for apparatus 10, as there is with some of the pre-existing gaskets having a shim only on one side, there is no need for electronic eye or other vision equipment to monitor the placement of the parts. A typical tape and reel can simply be used and the parts can be picked and placed as desired without any particular regard for orientation. This greatly speeds processing and manufacture of parts.

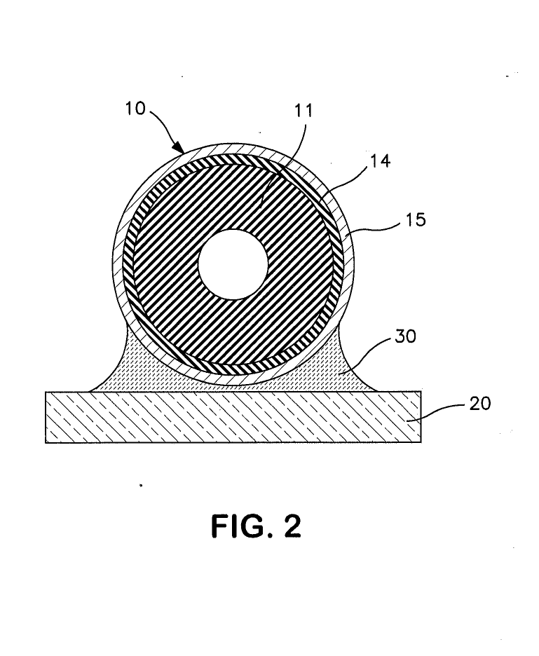

In addition, with reference to FIG. 2, because metal layer 15 is metal, the apparatus 10 is more reliably soldered to a support 20, for example a printed circuit board. That is, using solder 30, a secure attachment can be produced using the inventive apparatus. The strength of the attachment between the apparatus 10 and support 20 may be determined by conducting a peel strength test. This test may be conducted on mechanical test equipment, for example an SP2000 model available from IMASS, in Accord, Mass. A steel probe, wrapped in rubber simulates the finger of a person peeling the apparatus 10 from support 20. The bottom of the probe is positioned 30% to 50% of the apparatus 10 height above the support. After the probe is positioned adjacent to the apparatus, the probe moves rapidly, 75 inches per minute for example, in the direction of the apparatus in a peeling motion. The maximum load recorded by the test equipment may be considered the peel strength of the solder joint between the apparatus 10 and support 20. In the case of an apparatus 10 with a square cross-section, 1.5 mm by 1.5 mm and a length of 8 mm, a peel strength, using the method described above, of 900 g is achievable. Parts with the same dimensions fabricated using conventional constructions achieve a peel strength of only 350 g. Parts with a peel strength as defined above of 900 g or more are “solderable” as that term is used herein.

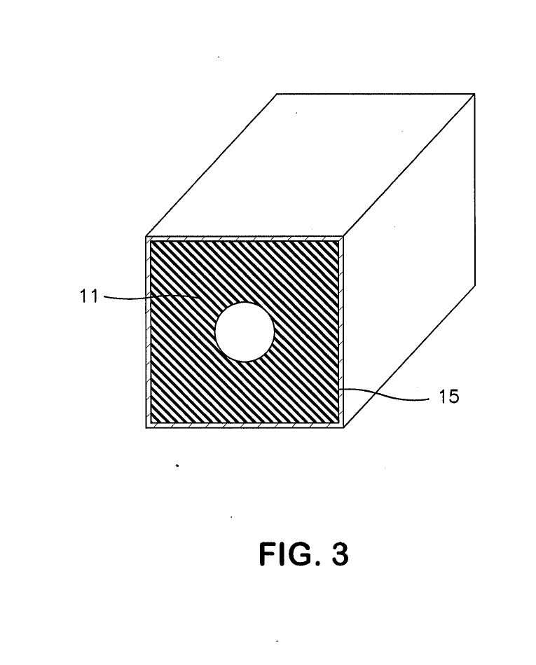

The existence of conductive elastomer layer 14 is preferred because it helps permit the plating of metal layer 15 around the outside of apparatus 10. In an alternative embodiment, however, compressible elastomeric substrate 11 is itself conductive and plated with metal layer 15 without conductive elastomeric layer 14 (as illustrated, for example in FIG. 3).

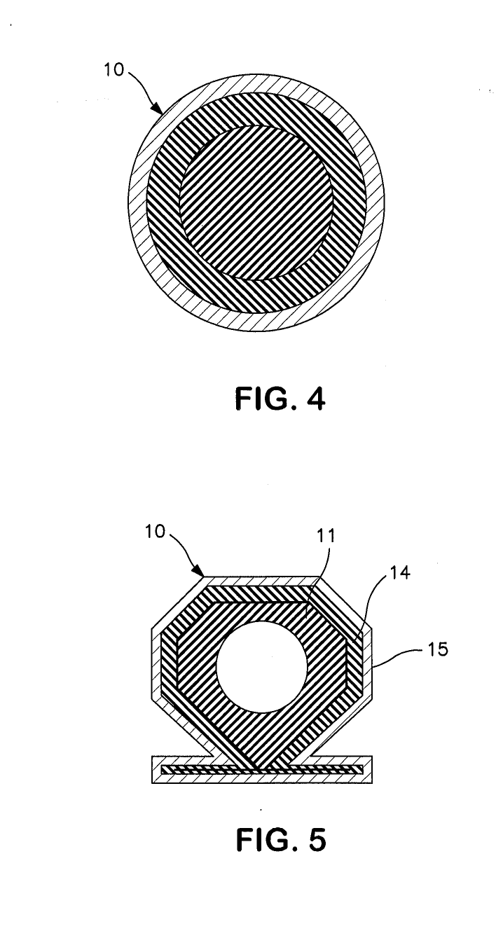

Also advantageously, the present invention allows for the fabrication of parts with a wide variety of cross-sections in alternative embodiments such as circular (FIG. 4), elliptical, square, rectangular, triangular, D-shaped, P-shaped U-shaped or irregular (FIG. 5). Additionally, the apparatus 10 may have features smaller than 1 mm which would enable use in applications where a very small form factor is required. With this invention, size limitations of known product constructions such as those using a separate metal shim are addressed and resolved by eliminating the need for a separate metal component mechanically attached to the compressible substrate. As electronic devices continue to decrease in size and form factor, smaller grounding and EMI gasket solutions are needed so that space required to accommodate these solutions on the PCBs and other supports are minimized.

Another characteristic of the present invention is that the DC resistance is comparable to that of known devices. The DC resistance is measured as the resistance of the apparatus 10 while compressed to a set compression height between two highly conductive plates. For example, the DC resistance of a part with 8 mm long part with 1.5 mm square cross-section is less than 50 mOhm when compressed to 75% of its original height.

Another advantage of the present invention is that because it is compressible and resilient, it performs better than known devices after repeated stresses.

According to the present invention, it is preferable to make a conductive gasket or grounding pad as a continuous process. A base material formed of the compressible elastomeric substrate and the conductive elastomeric outer layer adjacent the resilient elastomeric substrate is formed preferably by coextrusion as described in U.S. Pat. No. 4,968,854, which is incorporated herein by reference as described above. This base material is then electroplated or otherwise coated with a metal as described above to enable solder attachment to a support. Razor blades, lasers, or the like are then optionally used to cut the continuous conductive gasket or grounding pad into a plurality of discrete conductive gaskets or grounding pads. Alternatively, each base material may be first cut into discrete, stand-alone parts, and then plated to enable solderability.

While particular embodiments of the present invention have been illustrated and described herein, the present invention should not be limited to such illustrations and descriptions. It should be apparent that changes and modifications may be incorporated and embodied as part of the present invention within the scope of the following claims.

What is claimed is:

1. An apparatus comprising:
a. a compressible substrate having at least one side surface and two ends,
b. a conductive layer adjacent to all of said side surfaces of said compressible substrate, and
c. a metal layer adjacent to said conductive layer.

2. An apparatus as defined in claim 1 wherein said apparatus is solderable.

3. An apparatus as defined in claim 1 wherein said compressible substrate comprises an elastomer.

4. An apparatus as defined in claim 1 wherein said conductive layer comprises a conductive elastomer comprised of an elastomer having conductive particles impregnated therein.

5. An apparatus as defined in claim 4 wherein said conductive particles are selected from the group consisting of silver, nickel, carbon, copper, aluminium, gold, tin, platinum, palladium, and combinations and alloys thereof.

6. An apparatus as defined in claim 1 wherein at least one of said compressible substrate and said conductive layer is comprised of a material selected from the group consisting of silicone, silicone gum, rubber, fluorocarbon, fluorosilicon, EPDM, PTFE, ePTFE, and combinations thereof.

7. An apparatus as defined in claim 1 wherein said metal is a metal plating or coating.

8. An apparatus as defined in claim 1 wherein said metal is selected from the group consisting of copper, nickel, silver, gold, tin, chromium, and combinations and alloys thereof.

9. An apparatus as defined in claim 7 wherein said metal is an electrolytically plated metal.

10. An apparatus as defined in claim 7 wherein said metal is an electrolessly plated metal.

11. An apparatus as defined in claim 7 wherein said metal is vapor deposited metal.

12. An apparatus as defined in claim 7 wherein said metal is a combination of one or more of an electrolytically plated metal, an electrolessly plated metal, a vapor deposited metal.

13. An apparatus as defined in claim 1 wherein said apparatus has a substantially round cross-section.

14. An apparatus as defined in claim 1 wherein said compressible elastomer substrate comprises a plurality of side surfaces.

15. An apparatus as defined in claim 1 wherein said apparatus has a quadrilateral cross-section.

16. An apparatus as defined in claim 15 wherein said apparatus has a rectangular cross-section.

17. An apparatus as defined in claim 15 wherein said apparatus has a substantially square cross-section.

18. An apparatus as defined in claim 1 wherein said apparatus has an irregular cross-section.

19. An apparatus as defined in claim 1 wherein said apparatus is hollow.

20. An apparatus as defined in claim 1 wherein said apparatus is compressible to 75% of its height with an applied load less than 500 pounds per square inch.

21. An apparatus as defined in claim 20 wherein said apparatus has a DC resistance less than 50 mOhms when compressed to 75% of its height.

22. An apparatus comprising:
a. a compressible electrically conductive substrate having side surfaces, and
b. a metal layer adjacent to said side surfaces.

23. An apparatus comprising:
a. a compressible elastomeric substrate with a quadrilateral cross-section having a plurality of side surfaces and two ends,
b. a conductive elastomeric layer adjacent to all of said side surfaces of said compressible elastomeric substrate, and
c. a metal layer adjacent to said conductive layer,
d. wherein said apparatus is solderable.

24. A method of making a conductive gasket or grounding pad comprising the steps of
a. providing a continuous base material having a compressible elastomeric substrate and a conductive elastomeric outer layer adjacent said compressible elastomeric substrate;
b. metalizing said continuous base material to form a continuous conductive gasket or grounding pad, and
c. cutting said continuous conductive gasket or grounding pad into a plurality of discrete conductive gaskets or grounding pads.

25. A method of forming an EMI shielding gasket comprising soldering a plurality of apparatus as defined in claim 1 onto a support.

26. A method as defined in claim 25 wherein said support is a printed circuit board.

27. A method as defined in claim 25 further comprising using surface mount technology equipment to deposit said apparatus.

28. A method of forming grounding pads comprising soldering at least one apparatus as defined in claim 1 onto a support.

29. A method of forming grounding pads as defined in claim 28 wherein said support is a printed circuit board.

30. A method of forming a conductive path comprising soldering at least one of the apparatus as defined in claim 1 onto a support.

31. A method as defined in claim 30 wherein said at least one apparatus is soldered onto a printed circuit board.
